(19) United States
(12) Patent Application Publication
(10) Pub. No.: US 2019/0190505 A1
(43) Pub. Date: Jun. 20, 2019

(54) DELAY CONTROL CIRCUITS

(71) Applicant: SAMSUNG ELECTRONICS CO., LTD., Suwon-si (KR)

(72) Inventors: Shin Young YI, Seoul (KR); Kwan Yeob CHAE, Seoul (KR)

(73) Assignee: SAMSUNG ELECTRONICS CO., LTD., Suwon-si (KR)

(21) Appl. No.: 16/039,050

(22) Filed: Jul. 18, 2018

(30) Foreign Application Priority Data
Dec. 19, 2017 (KR) 10-2017-0174953

(51) Int. Cl. H03K 5/131; H03K 5/14; H03K 5/135; H03H 11/26

(52) U.S. Cl. CPC H03K 5/131; H03K 5/14; H03K 2005/00071; H03H 11/265; H03K 5/135

(57) ABSTRACT

A delay control circuit includes: a first step delay cell including a first switch having a first end connected to a first node, and a first capacitor connected to a second end of the first switch; a second step delay cell including a second switch having a first end connected to a second node, and a second capacitor connected to a second end of the second switch; and a first inverter configured to couple an output signal of the first step delay cell to an input of the second step delay cell, wherein the first switch and the second switch are turned on and off by a same control signal.

### CROSS-REFERENCE TO RELATED APPLICATION

This application is based on and claims priority under 35 U.S.C. § 119 to Korean Patent Application No. 10-2017-0174953, filed on Dec. 19, 2017, in the Korean Intellectual Property Office, the disclosure of which is incorporated by reference in its entirety herein.

### BACKGROUND

### 1. Field

Example embodiments provided herein relate to a delay control circuit, and more specifically, to a delay control circuit in which sensitivity to process, voltage and temperature (PVT) variation is low and a duty ratio is maintained.

### 2. Description of the Related Art

Precision of a clock is very important in many fields of digital systems. Especially, a clock received from the outside and an internal clock need to be synchronized. Also, the performance of the digital system may be influenced by how accurately the duty ratio is controlled. However, since a quantization error occurs due to the characteristics of the digital system, an improvement in accuracy of the clock becomes increasingly difficult.

A delay line may be used to synchronize the clock received from the outside and the internal clock. The clock received from the outside passes through the delay line and has a predetermined delay time. The delay line may change a driving strength or change a an output capacitance seen by a driving stage to generate the delay time. Specifically, the delay time may be adjusted by changing the slope of the signal passing through the delay line.

However, when a PVT variation occurs due to an external factor, a delay error may be produced by the delay line circuit. As a delay time generated by the delay line becomes longer, the delay error may increase exponentially. Additionally, when the signal passes through the delay line at a skewed corner, the duty ratio may change. A skewed corner, in some technologies, is associated with NMOS and PMOS devices which are coupled in a circuit.

### SUMMARY

One or more example embodiments provide a delay control circuit having low sensitivity to PVT variation.

Further, one or more example embodiments provide a delay control circuit in which a duty ratio of a signal is maintained before and after passing through the delay control circuit.

According to an aspect of an example embodiment, there is provided a delay control circuit including: a first step delay cell including a first switch having a first end connected to a first node, and a first capacitor connected to a second end of the first switch; a second step delay cell including a second switch having a first end connected to a second node, and a second capacitor connected to a second end of the second switch; and an inverter configured to couple an output signal of the first step delay cell to an input of the second step delay cell, wherein the first and the second switches are turned on and off by a control signal.

According to an aspect of another example embodiment, there is provided a delay control circuit including a first step delay cell which is configured to receive a first signal and includes a first node; a second step delay cell which is configured to provide a second signal and includes a second node; a control signal input configured to receive a control signal, wherein the control signal input is coupled to the first step delay cell and to the second step delay cell; and a first inverter which is configured to receive a third signal from the first step delay cell and to output a fourth signal to the second step delay cell, wherein when the first signal is enabled and the control signal indicates a minimum delay value, a first voltage level of the first node decreases with a first slope, and a second voltage level of the second node increases with a second slope.

According to an aspect of an example embodiment, there is provided a delay control circuit configured to receive a first signal as an input and to delay the first signal, the delay control circuit including: k step delay cells including first and second step delay cells, wherein k is an even integer greater than zero; a first inverter disposed between the first step delay cell and the second step delay cell; and a second inverter coupled to an output of the second step delay cell, wherein the first step delay cell is configured to provide a second signal in response to the first signal, the first inverter is configured to provide a third signal in response to the second signal, the second step delay cell is configured to provide a fourth signal in response to the third signal, the second inverter is configured to provide a fifth signal in response to the fourth signal, a second duty ratio of the second signal is greater than a first duty ratio of the first signal, a third duty ratio of the fifth signal is less than the second duty ratio, and the third duty ratio approximately matches the first duty ratio.

The aspects of the present inventive concept are not limited to those mentioned above and another aspect which is not mentioned can be clearly understood by those skilled in the art from the description below.

### BRIEF DESCRIPTION OF THE DRAWINGS

The above and/or other aspects will become apparent and more readily appreciated from the following description of exemplary embodiments, taken in conjunction with the accompanying drawings in which:

FIGS. 1A and 1B are example circuit diagrams for explaining a step delay cell;

FIG. 2 is an example timing diagram for explaining the voltage for each node of the step delay cell when a power supply noise is relatively small;

FIG. 3 is an example timing diagram for explaining the voltage for each node of the step delay cell when the power supply noise is relatively large;

FIG. 4 is a graph illustrating the magnitude of the delay error to an average value of a slope of a second signal P2;

FIGS. 5 and 6 are example circuit diagrams for describing a delay control circuit according to some embodiments;

FIG. 7 is an example circuit diagram for describing the configuration of the delay control circuit according to some embodiments;

FIGS. 8A and 8B are example circuit diagrams for explaining capacitors and switches of the delay control circuit according to some embodiments;

FIGS. 9A, 9B, and 9C are example timing diagrams for explaining the voltage for each node of the delay control circuit according to some embodiments;

FIGS. 10A and 10B are example tables for describing the code of the control signal according to some embodiments;

FIG. 11 is an example diagram for explaining occurrence of a duty error at a skewed corner;

FIG. 12A is an example view for illustrating a change in the duty ratio of the signal having passed through the delay control circuit according to some embodiments at the SF corner (slow-fast corner);

FIG. 12B is an example view for illustrating a change in duty ratio of the signal having passed through the delay control circuit according to some embodiments at the FS corner (fast-slow corner); and

FIG. 13 is an example block diagram illustrating the structure of the memory which utilizes the delay control circuit according to some embodiments.

### DETAILED DESCRIPTION

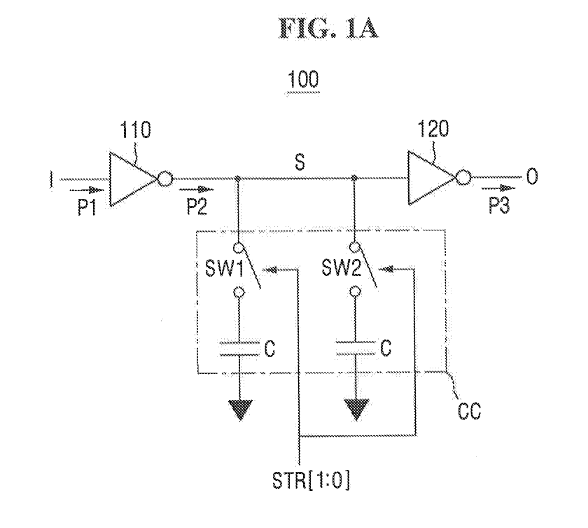

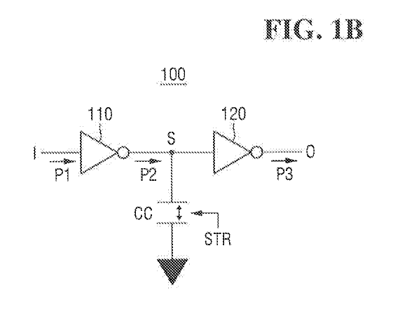

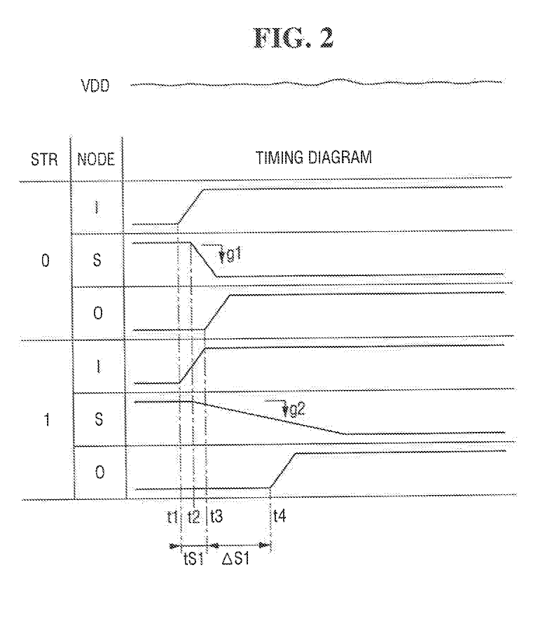

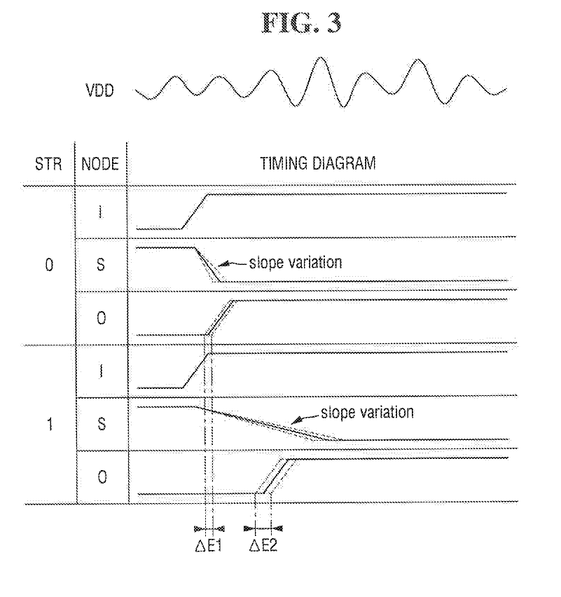

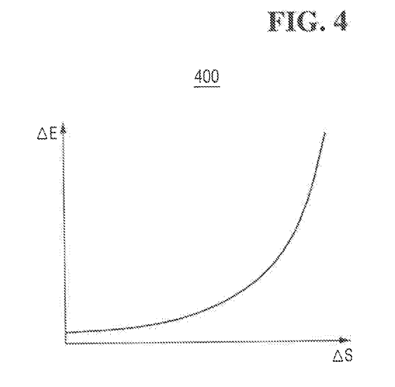

FIGS. 1A and 1B are example circuit diagrams for explaining a step delay cell. FIG. 2 is an example timing diagram for explaining the voltage for each node of the step delay cell when a power supply noise is relatively small. FIG. 3 is an example timing diagram for explaining the voltage for each node of the step delay cell when the power supply noise is relatively large. FIG. 4 is a graph illustrating the magnitude of the delay error to an average value of a slope of a second signal P2.

Referring to FIGS. 1A and 1B, a step delay cell 100 may include an input inverter 110, an output inverter 120, and a variable capacitor CC.

An input stage of the input inverter 110 may be connected to an input node I. An output stage of the input inverter 110 may be connected to a delay node S. An input stage of the output inverter 120 may be connected to the delay node S. An output stage of the output inverter 120 may be connected to an output node O.

The input inverter 110 may invert a first signal P1 provided to the input node I. The input inverter 110 may invert the first signal P1 and provide the first signal P1 to the delay node S in the form of a second signal P2. The output inverter 120 receives the second signal P2, inverts the second signal P2, and may provide the inverted second signal P2 to the output node O in the form of a third signal P3.

One end of the variable capacitor CC may be connected to the delay node S. The other end of the variable capacitor CC, for example, may be grounded. The capacitance of the variable capacitor CC may be controlled by a control signal STR. STR generally represents a control signal which may be a scalar or a vector. That is, STR may be composed of a single binary signal or may be composed of two or more constituent control signals.

As illustrated in FIG. 1A, in some embodiments, the variable capacitor CC may include switches SW1 and SW2, and two capacitors C, connected to the switches SW1 and SW2. A control signal STR[1:0] may control turning on/off of the switches SW1 and SW2. Depending on the switch positions, each of the capacitors C may be coupled to or decoupled from the delay node S, in accordance with the turning on/off of the switches SW1 and SW2. In other words, the control signal STR[1:0] may control the switches SW1 and SW2 to adjust the capacitance of the variable capacitor CC. For example, if both switches SW1 and SW2 are turned off, the capacitance of the variable capacitor CC may be zero. For example, if one of the switches SW1 and SW2) is turned on and the other one is turned off, the capacitance of the variable capacitor CC may be the capacitance of C. On the other hand, if both switches SW1 and SW2 are turned on, the capacitance of the variable capacitor CC may be twice the capacitance of C. Therefore, the control signal STR[1:0] may control the capacitance of the variable capacitor CC by controlling the turning on/off of the switches SW1 and SW2.

Throughout the disclosure, coupling or connecting a capacitor to a node internal to a step delay cell may be referred to as “shorting” (closing the switch, the switch is on) and decoupling or disconnecting the capacitor from the node may be referred to as “open” (the switch is open, cut, or off).

Although FIG. 1A illustrates a configuration in which the variable capacitor CC includes two switches SW1 and SW2 and two capacitors C, the embodiments provided herein are not limited thereto. For example, the variable capacitor CC may include a plurality of capacitors, and a plurality of switches capable of adjusting short/opening thereof.

As illustrated in FIG. 1B, in some embodiments, the control signal STR may adjust the distance between pole plates of the variable capacitor CC. For example, when the distance between the pole plates of the variable capacitor CC increases by the control signal STR, the capacitance of the variable capacitor CC may be reduced. For example, when the distance between the pole plates of the variable capacitor CC decreases by the control signal STR, the capacitance of the variable capacitor CC may increase.

Those having ordinary skill in the technical field of this disclosure may achieve a variable capacitor CC in which capacitance is adjusted by the control signal STR in various ways. Hereinafter, for the convenience of explanation, a case where the variable capacitor CC includes a switch, and a capacitor connected to the switch will be described.

FIGS. 1A, 1B, 2, and 3 illustrate a case where the control signal STR has a low value or a high value. In some embodiments, the low value is expressed as 0 (logic low level), and the high value is expressed as 1 (logic high level) for convenience of explanation.

In some example embodiments, the inverted first signal P1, and the second signal P2 may be the same or different from each other.

For example, when the control signal STR is 0 in FIGS. 1A, 1B and 3, the capacitor C and the delay node S may be opened. The value STR=0 may be said to indicate a minimum delay value. In other words, when the control signal STR is 0, the switch SW connected to the capacitor C is opened, and the connection between the capacitor C and the delay node S may be cut. At this time, the inverted first signal P1, and the second signal P2 may be the same.

For example, when the control signal STR is 1, the capacitor C and the delay node S may be short. In other words, when the control signal STR is 1, the switch SW connected to the capacitor C is short, and the capacitor C and the delay node S may be connected to each other. At this time, the capacitor C may be charged with the inverted first signal P1. Also, because the capacitor C provides a capacitive load at the delay node S, the capacitor C will tend to charge or discharge depending on the state of the output connected to C. In such a case, the inverted first signal P1, and the second signal P2 may be different from each other while the capacitor C is charging or discharging.

Specifically, when the voltage level of the inverted first signal P1 increases, the capacitor C may be charged with the inverted first signal P1. Since the capacitor C is charged with the inverted first signal P1, the voltage level of the inverted first signal P1 may ramp up more slowly than the case where the capacitor C and the delay node S are opened (decoupled). In a simplified scenario, the capacitor C integrates the current from an inverter output. For a constant current, the resulting integral of the constant current is a ramp voltage function.

Further, when the voltage level of the inverted first signal P1 decreases, the capacitor C may discharge the charged electric charge to the delay node S. Since the electric charge is discharged from the capacitor C to the delay node S, the voltage level of the inverted first signal P1 may ramp down more slowly than the case where the capacitor C and the delay node S are opened (decoupled).

That is, the capacitor C may control the increasing and decreasing speed of the voltage level of the first signal P1 inverted through charging and discharging. Therefore, the control signal STR may control the opening/short (coupling/decoupling) of the capacitor C to control the increasing and decreasing speed of the voltage level of the inverted first signal P1. That is, since the control signal STR may control the increasing and decreasing slope of the inverted first signal P1 provided to the delay node S, it is possible to delay the increasing and decreasing speed of the inverted first signal P1. Therefore, the second signal P2 is a signal may be the inverted first signal P1 (without slope controlled) or may be a signal in which the slope of the inverted first signal P1 is controlled.

To facilitate the description and to aid in the understanding of the technical idea of the example embodiments provided herein, some characteristics of an inverter to be described below will be assumed. First, in the delay control circuit according to some example embodiments, a propagation delay may occur when the signal passes through the inverter. However, it is assumed that the propagation delay is much smaller than the delay due to the capacitor. Even though the propagation delay is illustrated in the drawings to be large enough to compare with the delay due to the capacitor, this is for ease of explanation, and the examples are not limited to the illustrated matters

In addition, the inverter according to some embodiments is assumed to have a threshold voltage of ½ point of the maximum voltage of the input and the minimum voltage of the input. The case where the input voltage is 0V to 10V will be described as an example. When the input of the inverter is less than 5V, the output of the inverter may be enabled. When the input of the inverter is 5V or more, the output of the inverter may be disabled. However, the embodiments are not limited to some characteristics of the inverter. Such an assumption is for facilitating the explanation and for helping understanding of those having ordinary skill in the technical field of the disclosure provided herein. The inverter achieved according to some embodiments may also have different characteristics. For example, the threshold voltage of an inverter may be higher or lower than a half of the maximum value of the input and the minimum value of the input of the inverter.

Referring to FIG. 2, FIG. 2 is a diagram illustrating a case where the noise of the power supply voltage VDD is relatively small. That is, FIG. 2 is a diagram illustrating a state in which the power supply voltage VDD is stably supplied.

First, the case where the control signal STR is 0, that is, the case where the capacitor C and the delay node S are opened (decoupled from each other) will be described. The first signal P1 may be provided to the input node I. The first signal P1 may be provided to the input stage of the input inverter 110. The input inverter 110 may invert the first signal P1 and provide it to the delay node S as the second signal P2. The voltage level of the first signal P1 may start to rise at time t1.

The second signal P2 may be provided to the delay node S. The voltage level of the second signal P2 may start to fall at time t2. The time t2 may be the time subsequent to the time t1 as illustrated in the drawings. That is, the falling time of the voltage level of the second signal P2 may be later than the rising time of the voltage level of the first signal P1. The time t2 may be subsequent to the time t1 due to the propagation delay of the input inverter 110. The second signal P2 may be reduced from the time t2 at the first slope g1.

If the output inverter 120 inverts the second signal P2 and provides it to the output node O, a third signal P3 may be provided to the output node O. The voltage level of the third signal P3 may start to rise at time t3. The time t3 may be a time subsequent to the time t2. That is, the rising time of the voltage level of the third signal P3 may be later than the falling time of the voltage level of the second signal P2. The time t3 may be subsequent to the time t2 due to the propagation delay of the output inverter 120.

At the input node I, the initial rising time of the voltage level of the first signal P1 may be t1 (an upward ramp transition begins). On the other hand, at the output node O, the initial rising time of the voltage level of the third signal P3 may be t3. When the control signal STR is 0, the total delay time may be t3-t1. Since the capacitor C is opened to (decoupled from) the delay node S when the control signal STR is 0, the total delay time may be caused by the input inverter 110 and the output inverter 120. That is, the propagation delay time tS1 due to the input inverter 110 and the output inverter 120 may be t3-t1.

Next, the case where the control signal STR is 1, that is, the case where the capacitor C and the delay node S are short (coupled) will be described. The first signal P1 may be provided to the input node I. The first signal P1 may be provided to the input stage of the input inverter 110. The input inverter 110 may invert the first signal P1 and provide it to the delay node S. The voltage level of the first signal P1 may start to rise at the time t1.

The second signal P2 may be provided to the delay node S. The voltage level of the second signal P2 may start to fall at the time t2. The time t2 may be the time subsequent to the time t1 as illustrated in the drawings. That is, the initial falling time of the voltage level of the second signal P2 may occur at a time later than the initial increasing time of the voltage level of the first signal P1. The time t2 may be subsequent to the time t1 due to the propagation delay of the input inverter 110.

The second signal P2 may be reduced at the time t2 with the second slope g2. The absolute value of the second slope g2 may be smaller than the absolute value of the first slope g1. That is, the falling speed of the second signal P2 when the control signal STR is 1 may be smaller than the falling speed of the second signal P2 when the control signal STR is 0. In other words, when the control signal STR is 1, the second signal P2 may ramp down at a slower rate than the case where the control signal STR is 0.

If the output inverter 120 inverts the second signal P2 and provides it to the output node O, the third signal P3 may be provided to the output node O. The voltage level of the third signal P3 may start to rise at the time t4. The time t4 may be subsequent to the time t3. The initial rising time of the voltage level of the third signal P3 when the control signal STR is 1 may be later than the initial rising time of the voltage level of the third signal P3 when the control signal STR is 0. The time t4 may be subsequent to the instant t3 because the charge charged in the capacitor C is discharged to the delay node S.

At the input node I, the initial increasing time of the voltage level of the first signal P1 may be t1. On the other hand, at the output node O, the initial increasing time of the voltage level of the third signal P3 may be t4. When the control signal STR is 1, the total delay time (tS1+ΔS1) may be t4-t1. As described above, the propagation delay time tS1 due to the input inverter 110 and the output inverter 120 may be t3-t1. Therefore, the delay time ΔS1 due to the capacitor C may be t4-t3.

In FIG. 2, the propagation delay time tS1 is illustrated to be large enough to compare with the delay time ΔS1, but in actual implementation, the propagation delay time tS1 may be much smaller than the delay time ΔS1. That is, the propagation delay time tS1 may be a negligibly small value.

Referring to FIG. 3, FIG. 3 is a diagram illustrating a case where the noise of the power supply voltage VDD is relatively large. That is, FIG. 3 is a diagram illustrating a state in which the power supply voltage VDD is not stably supplied; the voltage is not a simple clean constant. For the sake of convenience of explanation, repeated or same description of the contents described above will be omitted or briefly explained.

When the power supply voltage VDD is unstable, the total delay time may become uncertain (delay uncertainty). That is, when the power supply voltage VDD is unstable, the slope of the second signal P2 of the delay node S may be varied (slope variation). When the slope of the second signal P2 of the delay node S is varied, the initial rising time of the third signal P3 of the output node O may be varied. That is, the third signal P3 may have a delay error. The error may be positive or negative and of uncertain magnitude.

The delay error ΔE1 generated when the control signal STR is 0 may be smaller than the delay error ΔE2 generated when the control signal STR is 1. In other words, the delay error ΔE1 when the second signal P2 decreases according to a first slope g1 may be smaller than the delay time ΔE2 when the second signal P2 decreases according to a second slope g2. Refer to FIG. 4.

As illustrated in the graph 400 of FIG. 4, the x-axis is the magnitude of the delay time ΔS and the y-axis is the magnitude of the delay error ΔE. As the delay time ΔS increases, the delay error ΔE may increase exponentially. An exponential function has the form f(x)=a^{x}.

In conclusion, as the delay time ΔS increases, that is, as the absolute value of the slope of the second signal P2 is small, the delay error due to the fluctuation of the power supply voltage VDD may be relatively large. That is, as the absolute value of the slope of the second signal P2 is small, the delay error may be greatly influenced by external factors.

Although FIG. 3 illustrates that a delay error occurs in accordance with the voltage variation, the embodiments are not limited thereto. For example, the delay error may be generated in accordance with PVT variation (Process, Voltage, and Temperature variation). Generally, PVI variation refers to a process by which a chip is manufactured, a voltage under which it is operating and a temperature under which it is operating.

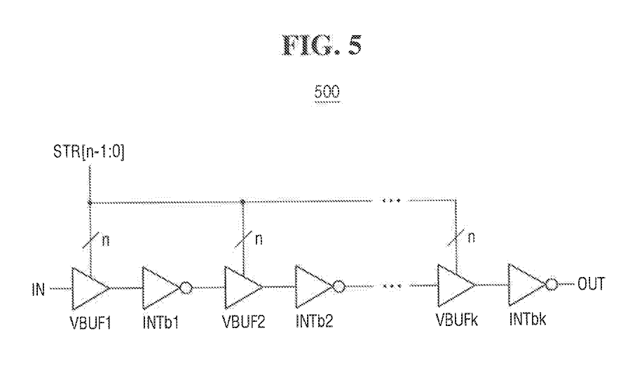

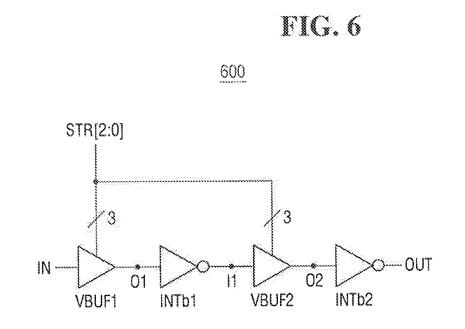

FIGS. 5 and 6 are circuit diagrams for describing a delay control circuit according to some example embodiments.

Referring to FIG. 5, a delay control circuit 500 according to some embodiments may include k step delay cells (VBUF1 to VBUFk) and k inverters (INTb1 to INTbk). Here, k may be an integer greater than 1 in some embodiments. In some other embodiments, k may be an even number greater than 1.

The outputs of the k step delay cells (VBUF1 to VBUFk) may be connected to the inputs of the k inverters (INTb1 to INTbk), respectively. For example, the output of the first step delay cell VBUF1 may be connected to the input of the first inverter INTb1. The output stage of the first inverter INTb1 may be connected to the input of the second step delay cell VBUF2.

The same n control signals (STR[n-1:0]) may be provided to each of the k step delay cells (VBUF1 to VBUFk). For example, n control signals (STR[n-1] to STR[0]) may be provided to the first step delay cell VBUF1. Also, the same n control signals (STR[n-1] to STR[0]) may be provided to the second step delay cell VBUF2.

FIG. 6 illustrates a case where k=2 and n=3 in the delay control circuit 500 of FIG. 5. For convenience of explanation, in some embodiments, the case where the delay control circuit 500 has k=2 and n=3, that is, the delay control circuit is the delay control circuit 600 of FIG. 6 is illustrated, but the embodiments are not limited thereto.

Referring to FIG. 6, the delay control circuit 600 according to some example embodiments may include first and second step delay cells VBUF1 and VBUF2 and first and second inverters INTb1 and INTb2.

First and second control signals STR[2:0] may be provided to the first and second step delay cells VBUF1 and VBUF2, respectively. In other words, the first, second, and third control signals STR[2], STR[1], and STR[0] may be provided to the first step delay cell VBUF1. Further, the first, second, and third control signals STR[2], STR[1], and STR[0] may be provided to the second step delay cell VBUF2.

In FIGS. 6 to 10B, each of the control signals STR[2], STR[1], and STR[0] may have low or high value. In some embodiments, for convenience of explanation, the low value is expressed as 0 (logic low level) and the high value is expressed as 1 (logic high level). For example, when the first control signal STR[2] is high, the second control signal STR[1] is low, and the third control signal STR[0] is low, the control signal may be expressed as [100].

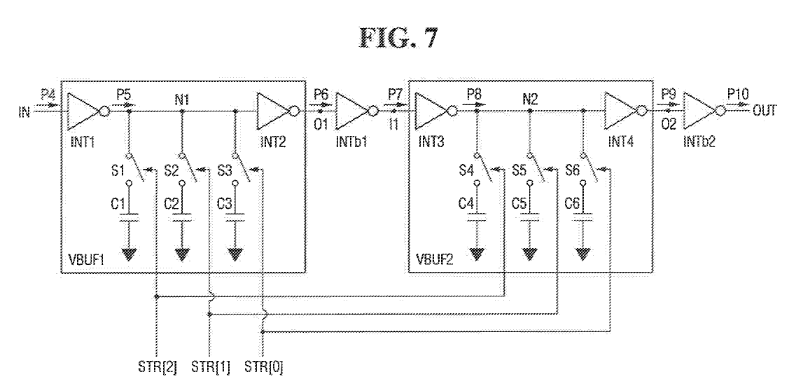

The input stage of the first step delay cell VBUF1 may be connected to the first input node IN. The output stage of the first step delay cell VBUF1 may be connected to the first output node O1. The input stage of the first inverter INTb1 may be connected to the first output node O1. The output stage of the first inverter INTb1 may be connected to the second input node I1. The input stage of the second step delay cell VBUF2 may be connected to the second input node I1. The output stage of the second step delay cell VBUF2 may be connected to the second output node O2. The input stage of the second inverter INTb2 may be connected to the second output node O2. The output stage of the second inverter INTb2 may be connected to the third output node OUT. The description will be made in more detail referring to FIG. 7.

FIG. 7 is a circuit diagram for describing the configuration of the delay control circuit according to some example embodiments.

Referring to FIG. 7, the first step delay cell VBUF1 may include a third inverter INT1, a fourth inverter INT2, first, second, and third switches S1, S2, and S3, and first, second, and third capacitors C1, C2, and C3).

The input stage of the third inverter INT1 may be connected to the first input node IN. The output stage of the third inverter INT1 may be connected to the first node N1. One end of the first switch S1 may be connected to the first node N1. The other end of the first switch S1 may be connected to one end of the first capacitor C1. The other end of the first capacitor C1, for example, may be grounded. One end of the second switch S2 may be connected to the first node N1. The other end of the second switch S2 may be connected to one end of the second capacitor C2. The other end of the second capacitor C2, for example, may be grounded. One end of the third switch S3 may be connected to the first node N1. The other end of the third switch S3 may be connected to one end of the third capacitor C3. The other end of the third capacitor C3, for example, may be grounded. The input stage of the fourth inverter INT2 may be connected to the first node N1. The output stage of the fourth inverter INT2 may be connected to the first output node O1.

The first, second, and third control signals STR[2], STR[1], and STR[0] may control turning on-off of the first, second, and third switches S 1, S2, and S3, respectively. For example, if the first control signal STR[2] is 1, the first switch S1 may be turned on. If the first switch S1 is turned on, the first capacitor C1 and the first node N1 may be short (coupled). If the first control signal STR[2] is 0, the first switch S1 may be turned off. If the first switch S1 is turned off, the first capacitor C1 and the first node N1 may be opened (decoupled).

The second step delay cell VBUF2 may include a fifth inverter INT3, a sixth inverter INT4, fourth, fifth, and sixth switches S4, S5, and S6, and fourth, fifth, and sixth capacitors C4, C5, and to C6.

The input stage of the fifth inverter INT3 may be connected to the second input node I1. The output stage of the fifth inverter INT3 may be connected to the second node N2. One end of the fourth switch S4 may be connected to the second node N2. The other end of the fourth switch S4 may be connected to one end of the fourth capacitor C4. The other end of the fourth capacitor C4, for example, may be grounded. One end of the fifth switch S5 may be connected to the second node N2. The other end of the fifth switch S5 may be connected to one end of the fifth capacitor C5. The other end of the fifth capacitor C5, for example, may be grounded. One end of the sixth switch S6 may be connected to the second node N2. The other end of the sixth switch S6 may be connected to one end of the sixth capacitor C6. The other end of the sixth capacitor C6, for example, may be grounded. The input stage of the sixth inverter INT4 may be connected to the second node N2. The output stage of the sixth inverter INT4 may be connected to the second output node O2.

The first, second, and third control signals STR[2], STR[1], and STR[0] may control the turning on-off of the fourth, fifth, and sixth switches S4, S5, and S6, respectively. In other words, the first control signal STR[2] may control the turning on/off of the first and fourth switches S1 and S4. The second control signal STR[1] may control the turning on/off of the second and fifth switches S2 and S5. The third control signal (STR[0]) may control the turning on/off of the third and sixth switches S3 and S6. For example, if the first control signal STR[2] is 1, the first and fourth switches S1 and S4 may be turned on. If the first control signal STR[2] is 0, the first and fourth switches S1 and S4 may be turned off.

The capacitance of the first capacitor C1 and the capacitance of the fourth capacitor C4 may be the same. The capacitance of the second capacitor C2 and the capacitance of the fifth capacitor C5 may be the same. The capacitance of the third capacitor C3 and the capacitance of the sixth capacitor C6 may be the same.

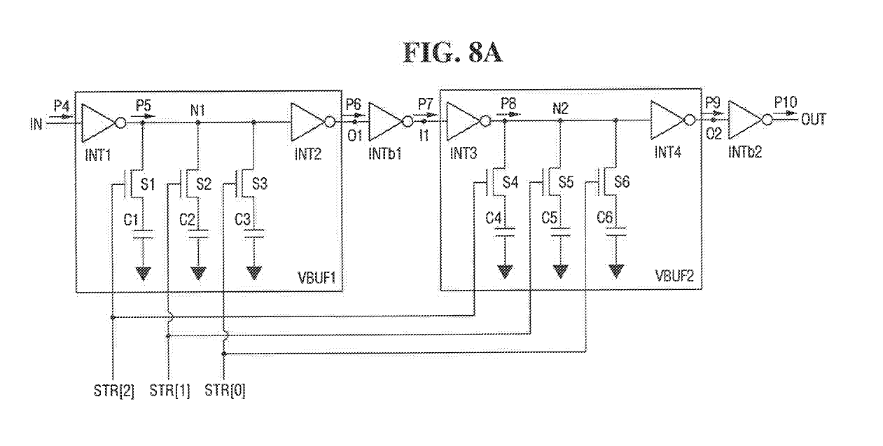

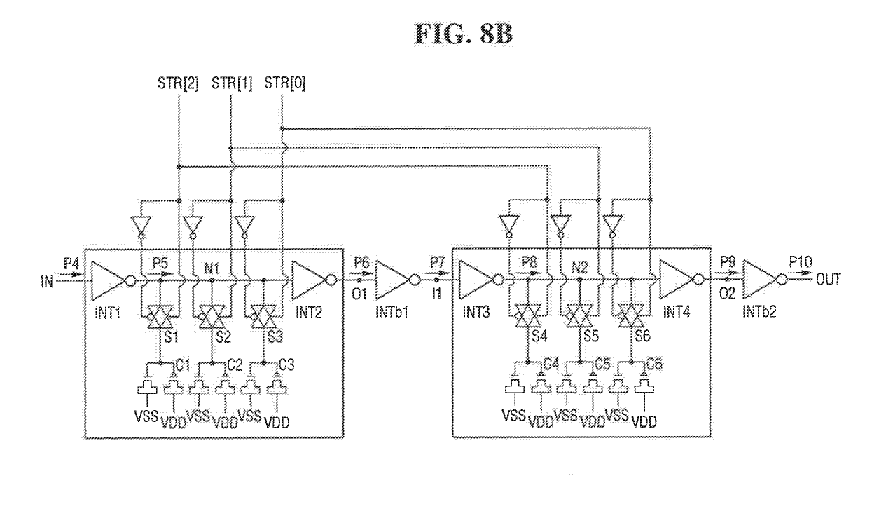

FIGS. 8A and 8B are example circuit diagrams for explaining capacitors and switches of the delay control circuit according to some embodiments.

Referring to FIG. 8A, in some embodiments, the first to sixth switches (S1 to S6) may be MOS transistors. The first, second, and third control signals STR[2], STR[1], and STR[0] may be provided to the gate of the MOS transistor. Although the first, second, third, fourth, fifth, and sixth switches S1, S2, S3, S4, S5 and S6 are illustrated as the NMOS transistors in FIG. 8A, the embodiments provided herein are not limited thereto. For example, the first, second, third, fourth, fifth, and sixth switches S1, S2, S3, S4, S5 and S6 may be PMOS transistors. Alternatively, for example, the first, second, third, fourth, fifth, and sixth switches S1, S2, S3, S4, S5 and S6 may be a combination of an NMOS transistor and a PMOS transistor.

Referring to FIG. 8B, in some embodiments, the first, second, third, fourth, fifth, and sixth switches S1, S2, S3, S4, S5 and S6 may be transmission gates. Also, in some embodiments, the first, second, third, fourth, fifth, and sixth capacitors C1, C2, C3, C4, C5, and C6 may be MOS capacitors.

Although FIGS. 8A and 8B describe examples of switches and capacitors of the delay control circuit according to some embodiments, the embodiments provided herein are not limited thereto. For example, the delay control circuit according to some embodiments may be achieved by the combination of FIGS. 8A and 8B. Those having ordinary skill in the technical field of this disclosure will be able to implement switches and capacitors in various ways.

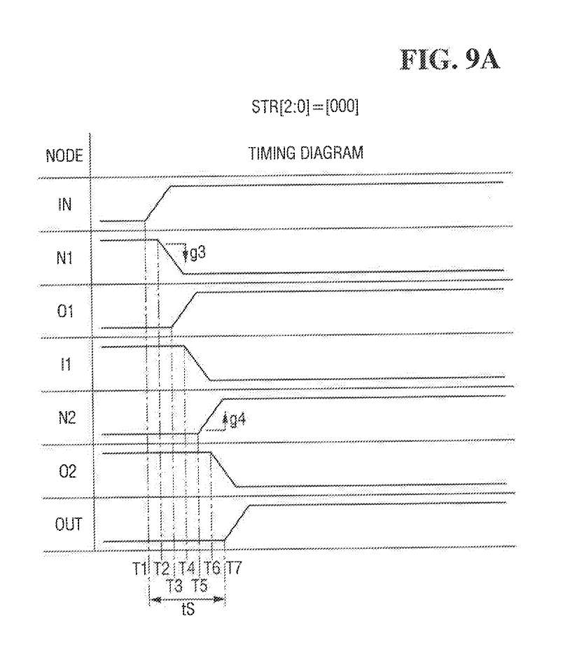

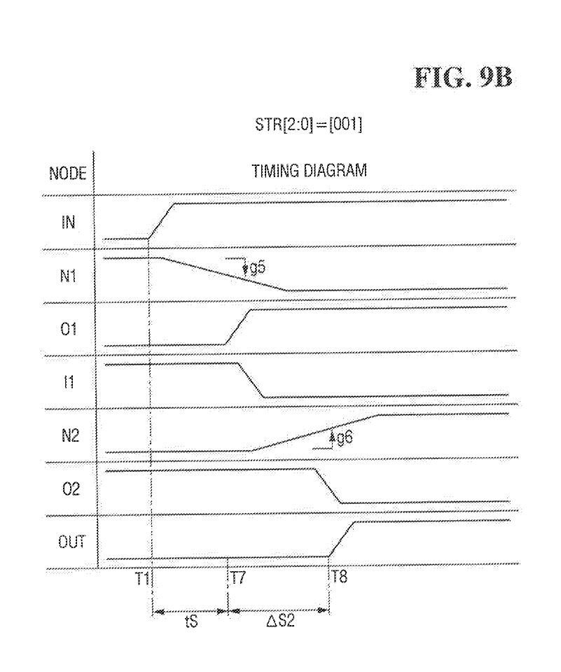

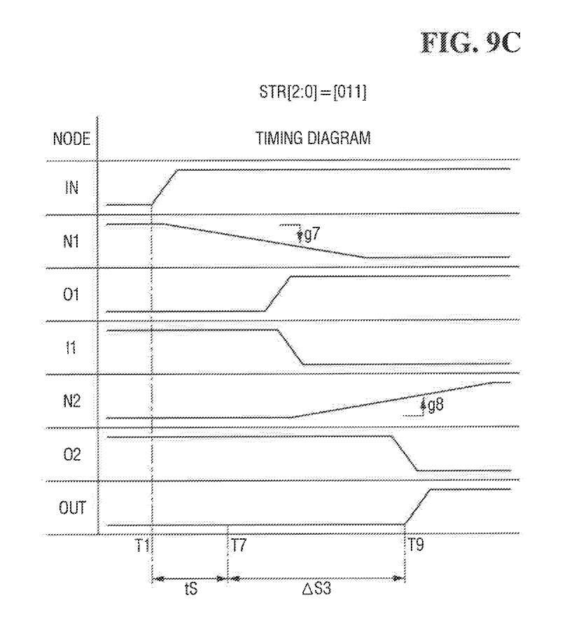

FIGS. 9A, 9B, and 9C are example timing diagrams for explaining the voltage for each node of the delay control circuit according to some embodiments.

For convenience of explanation, the signals provided to each node illustrated in FIGS. 7, 8A and 8B are defined. The signal of the first input node IN is defined as a fourth signal P4. The signal of the first node N1 is defined as a fifth signal P5. The signal of the first output node O1 is defined as a sixth signal P6. The signal of the second input node I1 is defined as a seventh signal P7. The signal of the second node N2 is defined as an eighth signal P8. The signal of the second output node O2 is defined as a ninth signal P9. The signal of the third output node OUT is defined as a tenth signal P10.

FIG. 9A is a diagram illustrating the voltage level for each node when the control signal STR[2:0] is [000], that is, when the values of the first, second, and third control signals STR[2], STR[1], and STR[0] are 0, respectively. The value [000] may be said to indicate a minimum delay value. That is to say, the timing chart of FIG. 9A illustrates the change in the voltage level of each node when the first to sixth switches S1, S2, S3, S4, S5 and S6 are opened.

The fourth signal P4 may be provided to the first input node IN. The fourth signal P4 may be provided to the input stage of the third inverter INT1. The voltage level of the fourth signal P4 may start to rise from the time T1. The third inverter INT1 may invert the fourth signal P4 and provide it to the first node N1.

The fifth signal P5 may be provided to the first node N1. The voltage level of the fifth signal P5 may start to fall at the time T2. The falling time of the voltage level of the fifth signal P5 may be later than the increasing time of the voltage level of the fourth signal P4. Time T2 may be subsequent to the time T1 due to the propagation delay of the third inverter INT1. The voltage level of the fifth signal P5 may be reduced from the time T2 according to a third slope g3.

The fourth inverter INT2 may invert the fifth signal P5 and provide it to the first output node O1, resulting in the sixth signal P6. The voltage level of the sixth signal P6 may start to rise at time T3. The rising time of the voltage level of the sixth signal P6 may be later than the falling time of the voltage level of the fifth signal P5. Time T3 may be subsequent to the time T2 due to the propagation delay of the fourth inverter INT2.

The first inverter INTb1 may invert the sixth signal P6 and provide it to the second input node I1 resulting in the seventh signal P7. The voltage level of the seventh signal P7 may start to fall at time T4. The time t4 may be a time subsequent to the time t3. That is, the falling time of the voltage level of the seventh signal P7 may be later than the rising time of the voltage level of the sixth signal P6. The time T4 may be subsequent to the time T3, due to the propagation delay of the first inverter INTb1.

The eighth signal P8 may be provided to the second node N2. The voltage level of the eighth signal P8 may start to rise at time T5 due to the signal P7. The rising time of the voltage level of the eighth signal P8 may be later than the falling time of the voltage level of the seventh signal P7. Time T5 may be subsequent to the time T4 due to the propagation delay of the fifth inverter INT3. The voltage level of the eighth signal P8 may increase from the time T5 according to a fourth slope g4. The absolute value of the third slope g3 and the absolute value of the fourth slope g4 may be the same. For example, the third slope g3 and the fourth slope g4 may have values with the same magnitude but with different signs.

The ninth signal P9 may be provided to the second output node O2 in response to the signal P8. The voltage level of the ninth signal P9 may start to fall at time T6. The falling time of the voltage level of the ninth signal P9 may be later than the rising time of the voltage level of the eighth signal P8. Time T6 may be subsequent to the time T5 due to the propagation delay of the sixth inverter INT4.

The tenth signal P10 may be provided to the third output node OUT in response to the signal P9. The voltage level of the tenth signal P10 may start to rise at time T7. The time T7 may be the time subsequent to the time T6. That is, the rising time of the voltage level of the tenth signal P10 may be later than the falling time of the voltage level of the ninth signal P9. Time T7 may be subsequent to the time T6 due to the propagation delay of the second inverter INTb2.

At the first input node IN, the increasing time of the voltage level of the fourth signal P4 may be T1. On the other hand, at the third output node OUT, the rising time of the voltage level of the tenth signal P10 may be T7. When the control signal STR[2:0] is [000], the total delay time may be T7-T1. That is, the propagation delay time tS due to the first, second, third, fourth, fifth, and sixth inverters INTb1, INTb2, INT1, INT2, INT3, and INT4 may be T7-T1.

The case where the control signal STR[2:0] is [001] will be described referring to FIG. 9B. For the sake of convenience of explanation, the repeated or same contents will be omitted or briefly explained.

When STR=[001] and a signal at the input terminal IN is enabled, the fifth signal P5 may ramp down according to a fifth slope g5. The absolute value of the fifth slope g5 may be smaller than the absolute value of the third slope g3. That is, the falling speed of the fifth signal P5 when the control signal STR[2:0] is [001] may be smaller than the falling speed of the fifth signal P5 when the control signal STR[2:0] is [000]. In other words, when the control signal STR[2:0] is [001] (an example indicating a non-minimum delay value, because some additional capacitive load is added), the fifth signal P5 may decay at a slower rate when the control signal STR[2:0] is [000] (indicating a minimum delay value because no additional capacitive load is added).

The eighth signal P8 may ramp up with a sixth slope g6. The absolute value of the sixth slope g6 may be smaller than the absolute value of the fourth slope g4. That is, the rising speed of the eighth signal P8 when the control signal STR[2:0] is [001] may be smaller than the rising speed of the eighth signal P8 when the control signal STR[2:0] is [000]. In other words, when the control signal STR[2:0] is [001], the eighth signal P8 may ramp up more slowly than when the control signal STR[2:0 is [000].

The absolute value of the fifth slope g5 and the absolute value of the sixth slope g6 may be the same. That is, the fifth slope g5 and the sixth slope g6 may have values with the same magnitude but with different signs.

At the first input node IN, the initial start time of the voltage level ramp up of the first signal P1 may be T1. On the other hand, at the third output node OUT, the initial start time of the voltage level ramp of the tenth signal P10 may be T8. When the control signal STR[2:0] is [001], the total delay time (tS+ΔS2) may be T8-T1. As described above, the propagation delay time tS due to the first, second, third, fourth, fifth, and sixth inverters INTb1, INTb2, INT1, INT2, INT3, and INT4 may be T7-T1. Therefore, the delay time ΔS2 due to the first, second, third, fourth, fifth, and sixth capacitors C1, C2, C3, C4, C5, and C6 may be T8-T7.

The case where the control signal STR[2:0] is [011] will be described referring to FIG. 9C. For the sake of convenience of explanation, repeated or same contents will be omitted or briefly explained.

When the signal at IN transitions to a high value, the fifth signal P5 may ramp down according to a seventh slope g7. The absolute value of the seventh slope g7 may be smaller than the absolute value of the fifth slope g5. That is, the falling speed of the fifth signal P5 when the control signal STR[2:0] is [011] may be smaller than the falling speed of the fifth signal P5 when the control signal STR[2:0] is [001]. In other words, when the control signal STR[2:0] is [011], the fifth signal P5 may ramp down more slowly than when the control signal STR[2:0] is [001]. This is consistent with STR=[011] indicating a greater delay than STR =[001].

The eighth signal P8 may be increased with the eighth slope g8. The absolute value of the eighth slope g8 may be smaller than the absolute value of the sixth slope g6. That is, the rising speed of the eighth signal P8 when the control signal STR[2:0] is [011] may be smaller than the rising speed of the eighth signal P8 when the control signal STR[2:0] is [001]. In other words, when the control signal STR[2:0] is [011], the eighth signal P8 may be increased to be slower than the case where the control signal STR[2:0] is [001].

The absolute value of the seventh slope g7 and the absolute value of the eighth slope g8 may be the same. That is, the seventh slope g7 and the eighth slope g8 may have values with the same magnitude but with different signs.

At the first input node IN, the increasing start time of the voltage level of the first signal P1 may be T1. On the other hand, at the third output node OUT, the increasing start time of the voltage level of the tenth signal P10 may be T9. When the control signal STR[2:0] is [011], the total delay time (tS+ΔS3) may be T9-T1. As described above, the propagation delay time tS due to the first, second, third, fourth, fifth, and sixth inverters INTb1, INTb2, INT1, INT2, INT3, and INT4 may be T7-T1. Therefore, the delay time ΔS3 due to the first to sixth capacitors C1, C2, C3, C4, C5, and C6 may be T9-T7.

In FIGS. 9A, 9B and 9C, the propagation delay time tS is illustrated to be large enough to compare with the delay times ΔS2 and ΔS3, but in the actual implementation, the propagation delay time tS may be the value that is much smaller than the delay times ΔS2 and ΔS3. That is, the propagation delay time tS may be negligibly small.

The description will be given with reference to FIGS. 1, 2, and 6 to 9C. In some embodiments, the propagation delay times tS1 and tS may be much smaller than the delay times ΔS1, ΔS2, and ΔS3. Therefore, it is assumed that the propagation delay times tS1 and tS are negligible.

The delay control circuit (500 of FIG. 5, and 600 of FIG. 6) according to some embodiments may include a plurality of step delay cells 100, and a plurality of inverters. When a target delay time is ΔS, in some embodiments, each of the k step delay cells VBUF1 to VBUFk included in the delay control circuit 500 may delay the input signal by ΔS/k.

In some embodiments, when the target delay time is ΔS, each of the first and second step delay cells VBUF1 and VBUF2 included in the delay control circuit 600 may delay the input signal by ΔS/2. That is to say, in FIG. 9B, each of the first and second step delay cells VBUF1 and VBUF2 may delay the fourth signal P4 by (ΔS2)/2. In FIG. 9C, each of the first and second step delay cells VBUF1 and VBUF2 may delay the fourth signal P4 by (ΔS3)/2.

Referring to FIG. 4, as the magnitude of the delay time ΔS increases, the delay error ΔE may increase exponentially. Therefore, since the delay control circuit 500 delays ΔS by ΔS/k for k times, the delay error ΔE may be reduced. That is, the delay control circuit 500 may be a circuit with small sensitivity to PVT variation. This improved accuracy due to using the factor 1/k is due to the properties of exponential functions. Similarly, since the delay control circuit 600 delays ΔS by ΔS/2 twice (k=2, for example), the delay error ΔE may be reduced.

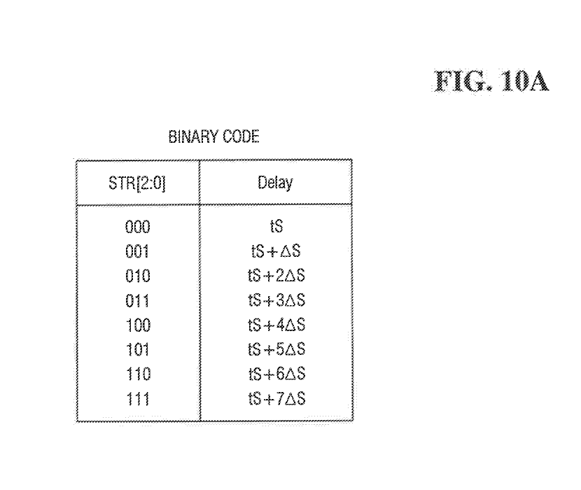

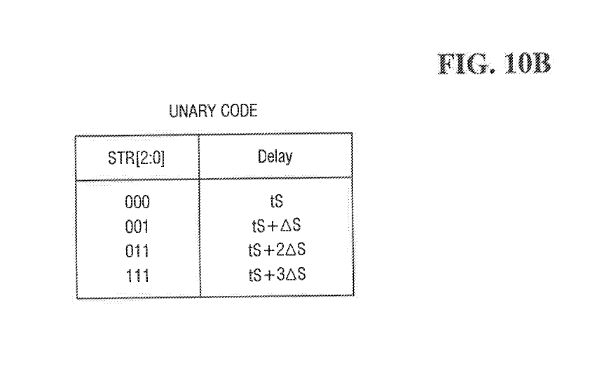

Referring to FIGS. 9B and 9C, in some embodiments, there may be a relation of ΔS3=2(ΔS2). Alternatively, in some other embodiments, there may be a relation of ΔS3=3(ΔS2). For specific explanation, reference is made to FIGS. 10A and 10B.

FIGS. 10A and 10B are example tables for describing the code of the control signal according to some embodiments.

Referring to FIGS. 6 and 10A, in some embodiments, the control signal STR[2:0] may follow a binary code. In other words, the control signal STR[2:0] may have the values of [000], [001], [010], [011], [100], [101], [110], and [111]. When the control signal STR[2:0] has the above respective values, the delay times (Delay) of the input signal may be 0, ΔS, 2ΔS, 3ΔS, 4ΔS, 5ΔS, 6ΔS, and 7ΔS, respectively. That is, each time the binary code of the control signal STR[2:0] increases by 1, the delay time (Delay) of the input signal may be increased by ΔS. In some embodiments, the control signal is applied to an ordered sequence of m capacitors in the step delay cell. A ratio between any two neighboring capacitors in the ordered sequence is ½. The ratio between a first capacitor in the sequence and the m^{th} capacitor is thus 2^{-(m-1)}. It is assumed that the propagation delay time tS due to the inverter is ignored. As an example, the capacitance ratio or proportions of the first capacitor C1, the second capacitor C2, and the third capacitor C3 may be 4:2:1. Further, the capacitance ratio of the fourth capacitor C4, the fifth capacitor C5, and the sixth capacitor C6 may be 4:2:1.

Therefore, in some embodiments, if the control signal STR[2:0] follows the binary code, there may be a relation of ΔS3=3(ΔS2).

Referring to FIGS. 6 and 10B, in some embodiments, the control signals STR[2:0] may follow a unary code or thermometer code. In other words, the control signals STR[2:0] may have values of [000], [001], [011], and [111]. A unary code is generally of the form 0 followed by zero or more 1s. When the control signal STR[2:0] has each of the above values, the delay time (Delay) of the input signal may be 0, ΔS, 2ΔS, and 3ΔS, respectively. That is, each time the unary code of the control signal STR[2:0] increases by 1, the delay time (Delay) of the input signal may be increased by ΔS. However, it is assumed that the propagation delay time tS due to the inverter is ignored. The capacitances of the first, second, third, fourth, fifth, and sixth capacitors C1, C2, C3, C4, C5, and C6 may be the same.

Therefore, in some embodiments, if the control signal STR[2:0] follows the unary code, there may be a relation of ΔS3=2(ΔS2).

In some embodiments, only the case where the voltage level of the input signal provided to the delay control circuit (500 in FIG. 5, and 600 in FIG. 6) increases is described, but the embodiments provided herein are not limited thereto. When the input signal decreases, a reverse operation of the operation described in some embodiments may be performed. For example, when the voltage level decreases at the first input node IN, the voltage of the first node N1 may increase. Also, when the voltage level decreases in the first input node IN, the voltage of the second node N2 may increase.

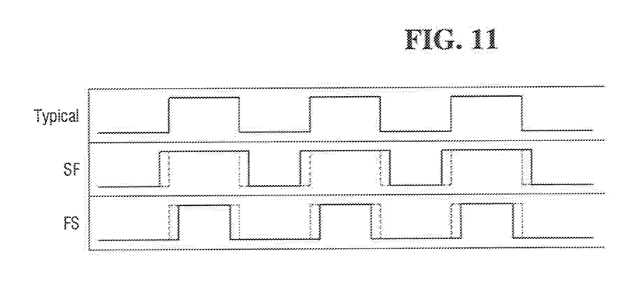

FIG. 11 is an example diagram for explaining occurrence of a duty error at a skewed corner.

Referring to FIG. 11, a typical signal (Typical) and signals (SF, FS) of the skewed corner are illustrated.

An SF corner (slow-fast corner) will be described on the basis of a typical signal (Typical). At the SF corner, the operation of the NMOS transistor may be slow, and the operation of the PMOS transistor may be fast. In other words, at the SF corner, the falling time of the signal level may be later than the falling time of the typical signal (Typical) level. Also, at the SF corner, the rising time of the signal level may be faster than the rising time of the typical signal (Typical) level. As a result, the duty ratio of the signal may increase at the SF corner.

An FS corner (fast-slow corner) will be described on the basis of the typical signal (Typical). At the FS corner, the operation of the NMOS transistor may be fast, and the operation of the PMOS transistor may be slow. In other words, at the FS corner, the falling time of the signal level may be faster than the falling time of the typical signal (Typical) level. Also, at the FS corner, the rising time of the signal level may be slower than the rising time of the typical signal (Typical) level. As a result, the duty ratio of the signal may be reduced at the FS corner.

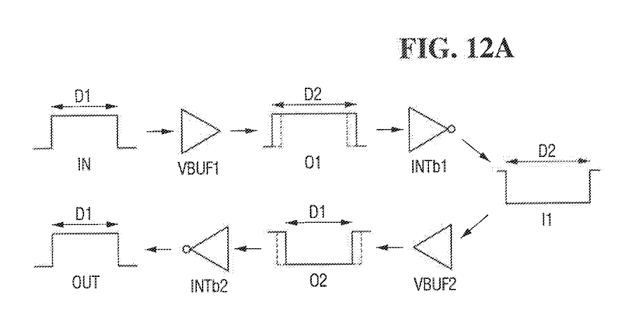

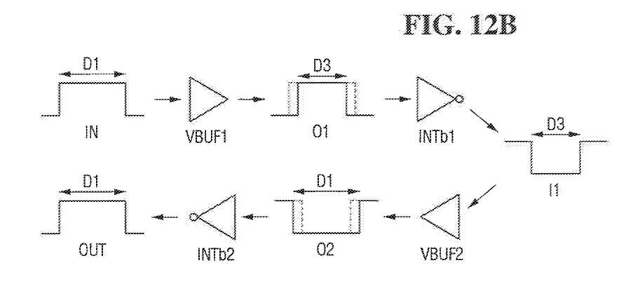

In other words, the duty ratio of the signal may increase at the corner of SF, and the duty ratio of the signal may decrease at the FS corner. A change in the duty ratio of the signal having passed through the delay control circuit according to some embodiments will be described referring to FIGS. 12A and 12B at the skewed corner.

FIG. 12A is an example view for illustrating a change in the duty ratio of the signal having passed through the delay control circuit according to some embodiments at the SF corner (slow-fast corner).

FIG. 12B is an example view for illustrating a change in duty ratio of the signal having passed through the delay control circuit according to some embodiments at the FS corner (fast-slow corner).

FIGS. 12A and 12B will be explained only from the viewpoint of the duty ratio, without considering the delay time of the signal passing through the delay control circuit according to some embodiments. Further, for the sake of convenience of explanation, it is assumed that the change in the duty ratio occurs only in the first and second step delay cells (VBUF1, VBUF2).

Referring to FIGS. 6 and 12A, an eleventh signal may be provided to the first input node IN. A width of the high level (e.g., 1) of the eleventh signal may be D1.

The fourth signal P4 may be provided to the first output node O1 through the first step delay cell VBUF1. At this time, a width of high level of the sixth signal P6 may be D2. Here, the width D2 of high level may be larger than the width D1 of high level.

At the SF corner, since the rising time becomes faster and the falling time becomes slower, the width of the high level may increase. In other words, when the fourth signal P4 passes through the first step delay cell VBUF1, the duty ratio may increase.

The sixth signal P6 may be provided to the second input node I1 through the first inverter INTb1. At this time, the width of the low level (e.g., 0) of the seventh signal P7 may be D2.

The seventh signal P7 may be provided to the second output node O2 through the second step delay cell VBUF2. At this time, the width of low level of the ninth signal P9 may be D1. At the SF corner, since the rising time becomes faster and the falling time becomes slower, the width of the low level may be reduced. In other words, when the seventh signal P7 passes through the second step delay cell VBUF2, the duty ratio may decrease.

The ninth signal P9 may be provided to the third output node OUT through the second inverter INTb2. The signal provided to the third output node OUT may have a high level width of D1.

As a result, the duty ratio of the signal provided to the first input node IN may be substantially the same as the duty ratio of the signal which is output to the third output node OUT. In other words, the duty ratio increased by passing through the first step delay cell VBUF1 may be cancelled with the duty ratio reduced by passing through the second step delay cell VBUF2. Therefore, at the SF corner, the duty ratio of the signal passing through the delay control circuit 600 according to some embodiments may be maintained. In this way the duty ratio of the final waveform emerging from the delay control circuit approximately matches the duty ratio of the initial waveform input to the delay control circuit.

The description will be made with reference to FIGS. 6 and 12B. For the sake of convenience of explanation, differences from the contents described above will be mainly described.

In the case of the FS corner, when the fourth signal P4 passes through the first step delay cell VBUF1, the duty ratio of the sixth signal P6 may decrease. When the seventh signal P7 passes through the second step delay cell VBUF2, the duty ratio of the ninth signal P9 may increase. That is, the duty ratio reduced by passing through the first step delay cell VBUF1 may be canceled with the duty ratio increased by passing through the second step delay cell VBUF2. Therefore, at the FS corner, the duty ratio of the signal passing through the delay control circuit 600 according to some embodiments may be maintained.

The description will be made with reference to FIGS. 5, 12A and 12B. For the sake of convenience of explanation, differences from the contents described above will be mainly described.

The delay control circuit 500 according to some embodiments may include an even number of step delay cells. In other words, k may be an even number.

At the FS corner, the duty ratio of the signal passed through the odd-numbered step delay cells (VBUF1, VBUF3, . . . , VBUFk−1) may increase. The duty ratio of the signal passed through the even-numbered step delay cells (VBUF2, VBUF4, . . . , VBUFk) may decrease. That is, the duty ratio increased by passing through the odd-numbered step delay cells (VBUF1, VBUF3, . . . , VBUFk−1) may be canceled with the duty ratio reduced by passing through the even-numbered step delay cells (VBUF2, VBUF4, . . . , VBUFk). Therefore, at the FS corner, the duty ratio of the signal passing through the delay control circuit 600 according to some embodiments may be maintained. In some situations, the various step delay cells of a delay circuit are all fabricated by the same process and experience the same voltage and temperature events during operation. Thus, the various step delay cells and exhibit the same PVT variations, if any. In the event that a particular fabricated delay circuit exhibits a skewed corner under given voltage and temperature conditions, embodiments provided herein compensate to provide an output clock waveform with a duty ratio that approximately matches a duty ratio of the clock waveform input to the delay circuit.

At the SF corner, the duty ratio of the signal passing through the odd-numbered step delay cells (VBUF1, VBUF3, . . . , VBUFk−1) may decrease. The duty ratio of the signal passing through the even-numbered step delay cells (VBUF2, VBUF4, . . . , VBUFk) may increase. That is, the duty ratio reduced by passing through the odd-numbered step delay cells (VBUF1, VBUF3, . . . , VBUFk−1) may be cancelled with the duty ratio increased by passing through the even-numbered step delay cells (VBUF2, VBUF4, . . . , VBUFk). Therefore, at the FS corner, the duty ratio of the signal passing through the delay control circuit 600 according to some embodiments may be maintained.

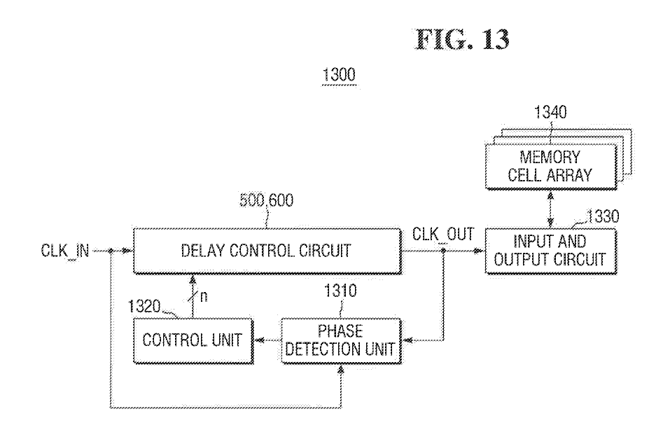

FIG. 13 is an example block diagram illustrating the structure of the memory which utilizes the delay control circuit according to some embodiments.

Referring to FIG. 13, the memory system 1300 may include a delay control circuit (500 of FIG. 5, and 600 of FIG. 6), a phase detection unit 1310, a control unit 1320, an input/output circuit 1330, and a memory cell array 1340.

The delay control circuit (500 of FIG. 5, and 600 of FIG. 6) may perform the same functions as those of the aforementioned contents. The input clock CLK_IN may be provided to the delay control circuit (500 of FIG. 5, and 600 of FIG. 6). The delay control circuit (500 of FIG. 5, and 600 of FIG. 6) may delay the input clock CLK_IN by a specific time and provide it to the output clock CLK_OUT.

The phase detection unit 1310 may compare the input clock CLK_IN with the output clock CLK_OUT. The phase detection unit 1310 may provide comparison data of the input clock CLK_IN and the output clock CLK_OUT to the control unit 1320.

The control unit 1320 may adjust the delay time of the delay control circuit (500 of FIG. 5, and 600 of FIG. 6), using the comparison data provided from the phase detection unit 1310.

The input/output circuit 1330 may receive the output clock CLK_OUT to read the value stored in the memory cell array 1340 or write the value on the memory cell array 1340. For example, in some embodiments, the output clock CLK_OUT is used to access the contents of the memory cell array 1340. The input clock CLK_IN may be an external clock waveform. The output clock CLK_OUT may be an internal clock waveform. The system 1300 synchronizes the output clock CLK_OUT with the input clock CLK_IN while limiting waveform distortion effects such as delay variation or duty cycle variation.

In concluding the detailed description, those skilled in the art will appreciate that many variations and modifications can be made to the example embodiments without substantially departing from the principles of the present disclosure. Therefore, the example embodiments are used in a generic and descriptive sense only and not for purposes of limitation.

What is claimed is:

1. A delay control circuit comprising:
a first step delay cell comprising:
a first switch having a first end connected to a first node, and
a first capacitor connected to a second end of the first switch;
a second step delay cell comprising:
a second switch having a first end connected to a second node, and
a second capacitor connected to a second end of the second switch; and
a first inverter configured to couple an output signal of the first step delay cell to an input of the second step delay cell, and
wherein the first switch and the second switch are turned on and off by a same control signal.

2. The delay control circuit of claim 1, wherein the first step delay cell further comprises a second inverter and a third inverter,
the second step delay cell further comprises a fourth inverter and a fifth inverter,
the delay control circuit further comprises a sixth inverter configured to couple an output of the second step delay cell to an output of the delay control circuit,
an output of the second inverter is coupled to an input of the third inverter at the first node,
the second inverter is configured to receive a first input signal,
an output of the third inverter is the output of the first step delay cell,
the first inverter is configured to couple the third inverter to the fourth inverter,
an output of the fourth inverter is coupled to an input of the fifth inverter at the second node,
an input of the fourth inverter is the input of the second step delay cell, and
an output of the fifth inverter is coupled to an input of the sixth inverter.

3. The delay control circuit of claim 1, wherein the first step delay cell further comprises a third switch and a third capacitor,
a first end of the third switch is connected to the first node and the third capacitor is connected to a second end of the third switch,
the second step delay cell further comprises a fourth switch and a fourth capacitor, and
a first end of the fourth switch is connected to the second node and the fourth capacitor is connected to a second end of the fourth switch.

4. The delay control circuit of claim 3, wherein the control signal comprises a first control signal and a second control signal,
the first control signal is configured to control turning on and off the first switch and the third switch, and
the second control signal is configured to control turning on and off the second switch and the fourth switch.

5. The delay control circuit of claim 4, wherein the control signal is provided in accordance with a binary code,
the first capacitor and the third capacitor have a first capacitance value,
the second capacitor and the fourth capacitor have a second capacitance value, and
a ratio between the first capacitance value and the second capacitance value is 2:1.

6. The delay control circuit of claim 4, wherein the control signal is provided in accordance with a unary code, and
the first capacitor, the second capacitor, the third capacitor and the fourth capacitor have a same capacitance value.

7. The delay control circuit of claim 1, wherein the first switch is a first transmission gate,
the second switch is a second transmission gate, and
the control signal is provided to a first gate of the first transmission gate and to a second gate of the second transmission gate.

8. The delay control circuit of claim 1, wherein the first switch is a first field effect transistor,
the second switch is a second field effect transistor, and
the control signal is provided to a first gate of the first field effect transistor and to a second gate of the second field effect transistor.

9. The delay control circuit of claim 1, wherein the first capacitor and the second capacitor are metal oxide semiconductor capacitors.

10. The delay control circuit of claim 1, wherein the control signal is provided in accordance with a binary code,
the first step delay cell comprises m capacitors in an ordered sequence, wherein the m capacitors comprise the first capacitor, and
a ratio between values of two neighboring capacitors in the ordered sequence is ½.

11. The delay control circuit of claim 1, wherein the control signal is provided in accordance with a unary code,
the first step delay cell comprises m capacitors, wherein the m capacitors comprise the first capacitor, and
the m capacitors have a same capacitance value.

12. A delay control circuit comprising:
a first step delay cell which is configured to receive a first signal and includes a first node;
a second step delay cell which is configured to provide a second signal and includes a second node;
a control signal input configured to receive a control signal, wherein the control signal input is coupled to the first and to the second step delay cells; and
a first inverter which is configured to receive a third signal from the first step delay cell and to output a fourth signal to the second step delay cell,
wherein when the first signal is enabled and the control signal indicates a minimum delay value, a first voltage level of the first node decreases with a first slope, and a second voltage level of the second node increases with a second slope.

13. The delay control circuit of claim 12, wherein, when the first signal is enabled and the control signal does not indicate a minimum delay value,
the first voltage level of the first node decreases with a third slope,
the second voltage level of the second node increases with a fourth slope,
absolute values of the third slope and the fourth slope are equal to each other, and
an absolute value of the third slope is smaller than an absolute value of the first slope.

14. The delay control circuit of claim 13, wherein the first step delay cell comprises a first capacitor and a first switch connected to the first capacitor,
the second step delay cell comprises a second capacitor, and a second switch connected to the second capacitor,
the control signal input is coupled to the first and to the second switches, and
when the control signal is does not indicate the minimum delay value, the control signal is configured to turn on the first and the second switches.

15. The delay control circuit of claim 14, wherein, when the first and the second switches are turned on and the first signal is enabled, the first capacitor is configured to discharge and the second capacitor is configured to charge.

16. The delay control circuit of claim 12, wherein the first step delay cell comprises a first capacitor, a first switch connected to the first capacitor, a second capacitor, and a second switch connected to the second capacitor,
the second step delay cell comprises a third capacitor, a third switch connected to the third capacitor, a fourth capacitor, and a fourth switch connected to the fourth capacitor,
the control signal comprises a first control signal and a second control signal,
the first switch and the third switch are configured to be controlled by the first control signal, and
the second switch and the fourth switch are configured to be controlled by the second control signal.

17. The delay control circuit of claim 16, wherein the first capacitor and the third capacitor have a first capacitance value,
the second capacitor and the fourth capacitor have a second capacitance value, and
a ratio between the first capacitance value and the second capacitance value is 2:1.

18. The delay control circuit of claim 16, wherein the first capacitor, the second capacitor, the third capacitor and the fourth capacitor have a same capacitance value.

19. The delay control circuit of claim 16, wherein, when the first and third switches are turned on,
the first capacitor is configured to discharge when the first switch is turned on and the first signal is enabled,
the third capacitor is configured to charge when the third switch is turned on and the first signal is enabled,
the second capacitor is configured to discharge when the second switch is turned on and the first signal is enabled, and
the fourth capacitor is configured to discharge when the fourth switch is turned on and the first signal is enabled.

20. A delay control circuit configured to receive a first signal as an input and to delay the first signal, the delay control circuit comprising:
k step delay cells including first and second step delay cells, wherein k is an even integer greater than zero;
a first inverter disposed between the first step delay cell and the second step delay cell; and
a second inverter coupled to an output of the second step delay cell,
wherein the first step delay cell is configured to provide a second signal in response to the first signal,
the first inverter is configured to provide a third signal in response to the second signal,
the second step delay cell is configured to provide a fourth signal in response to the third signal,
the second inverter is configured to provide a fifth signal in response to the fourth signal,
a second duty ratio of the second signal is greater than a first duty ratio of the first signal,
a third duty ratio of the fifth signal is less than the second duty ratio, and
the third duty ratio approximately matches the first duty ratio.
